(19) United States
(12) Patent Application Publication
(10) Pub. No.: US 2025/0316441 A1
(43) Pub. Date: Oct. 9, 2025

(54) CHARGED PARTICLE BEAM DEVICE AND METHOD FOR CONTROLLING CHARGED PARTICLE BEAM DEVICE

(71) Applicant: Hitachi High-Tech Corporation, Minato-ku, Tokyo (JP)

(72) Inventor: Hirokazu TAMAKI, Tokyo (JP)

(21) Appl. No.: 18/865,019

(22) PCT Filed: Jul. 29, 2022
(86) PCT No.: PCT/JP2022/029361

§ 371 Date: Nov. 12, 2024

(51) Int. Cl. H01J 37/20; H01J 37/244; H01J 37/26; H01J 37/28

(52) U.S. Cl. CPC H01J 37/20; H01J 37/244; H01J 37/265; H01J 37/28; H01J 2237/20207; H01J 2237/20292; H01J 2237/24475; H01J 2237/2802; H01J 2237/2817

(57) ABSTRACT

Provided is a charged particle beam device that includes a movement mechanism configured to hold and move a specimen, a particle source configured to output a charged particle beam, a detector configured to detect a signal generated by illuminating the specimen with the charged particle beam, and a controller configured to control the movement mechanism, the particle source, and the detector. The controller determines an illumination target region in the specimen according to the specimen, moves an illumination position of the charged particle beam in the illumination target region, and acquires a diffraction pattern according to a detection result of the detector at different illumination positions, and controls the movement mechanism based on an analysis result of the diffraction pattern to adjust tilt of the specimen.

### TECHNICAL FIELD

The present invention relates to a charged particle beam device and a method for controlling the charged particle beam device.

### BACKGROUND ART

When a specimen is observed using a charged particle beam device such as a scanning transmission electron microscope (STEM) and a transmission electron microscope (TEM), an image corresponding to a specimen structure projected in an orientation along which an electron beam is emitted is acquired. Focusing on an interface portion where two different substances are in contact with each other, a position of a boundary between the substances can be clearly confirmed in an observation image in a state where the interface is parallel to an emission orientation of the electron beam. On the other hand, when the interface is tilt relative to the emission orientation of the electron beam, since the interface portion is obliquely projected, the interface portion is observed in a manner of spreading in a tilt orientation in the observation image, and therefore it is difficult to clearly check the position. Accordingly, resolution of an acquired image changes according to a relationship between an orientation along which an electron beam is emitted and an orientation of a specimen.

A high-resolution image in which image bleeding is prevented is acquired by aligning the interface in the specimen structure in a traveling orientation of the electron beam to be emitted. A method for acquiring such a condition utilizes a matter that an orientation of the interface in the specimen structure and an orientation (a crystal orientation) of a crystal of a substrate portion coincide with each other in many cases in a semiconductor device specimen or the like formed on a crystal substrate. A tilt orientation of the entire specimen is adjusted so that the orientation of the crystal of the substrate portion coincides with an orientation of an emitted electron beam. A crystal orientation of a substrate portion of a specimen may be seen from an external appearance of the specimen. In the case of a specimen produced using a focused ion beam device, a crystal orientation inside the specimen differs from that seen from the external appearance, and cannot be determined from the external appearance. When the crystal orientation of the specimen cannot be determined from the external appearance, it is required to calculate a deviation amount and the orientation of the crystal orientation of the specimen using a diffraction pattern acquired by emitting an electron beam. At this time, when a region other than a crystal region of the substrate portion is included in a region illuminated with the electron beam, an acquired diffraction pattern is a mixture of a plurality of pieces of information, and it is difficult to calculate the deviation amount and the orientation of the crystal orientation. Therefore, the electron beam has a size that enables the electron beam to fall within the crystal region, and is emitted while being stopped at one position inside the crystal region, thereby acquiring a diffraction pattern.

For example, PTL 1 discloses a technique for detecting a diffraction pattern in a transmission charged particle microscope. By using a scanning assembly for inducing a relative motion between a diffraction pattern and a detector during recording of each frame, a maximum intensity value at each local position in the pattern draws a trajectory on the detector.

### CITATION LIST

### Patent Literature

PTL 1: US2019/0057836

### SUMMARY OF INVENTION

### Technical Problem

When a device slice specimen is observed using an STEM or a TEM, it is required to match a specimen orientation with an incident orientation of an electron beam at the time of observation in order to perform a length measurement with high accuracy. When the orientations deviate from each other, an interface is blurred and accuracy of the length measurement is lowered. The specimen orientation is adjusted by emitting an electron beam into a single crystal region serving as a reference in the specimen and changing specimen tilt while measuring deviation of the specimen orientation based on a diffraction pattern formed by the electron beam transmitted through the specimen.

During the adjustment work, since the electron beam is continuously emitted to a local region on the specimen, a decrease in crystallinity due to damage and specimen contamination are likely y to occur, and a failure in orientation adjustment and a decrease in accuracy may occur. Specifically, this can result in blurring of a diffraction pattern or disappearance of spots, and a clear diffraction pattern cannot be acquired. This is particularly likely to be a problem when a slice specimen such as a specimen of a semiconductor device manufactured by fine processing is observed or when a large current beam having a large convergence is used.

### Solution to Problem

A representative example of the invention disclosed in the present application is as follows. That is, a charged particle beam device includes a movement mechanism configured to hold and move a specimen, a particle source configured to output a charged particle beam, a detector configured to detect a signal generated by illuminating the specimen with the charged particle beam, and a controller configured to control the movement mechanism, the particle source, and the detector. The controller determines an illumination target region in the specimen according to the specimen, moves an illumination position of the charged particle beam in the illumination target region, acquires a diffraction pattern according to a detection result of the detector at different illumination positions, and controls the movement mechanism based on an analysis result of the diffraction pattern to adjust tilt of the specimen.

### Advantageous Effects of Invention

According to an aspect of the invention, it is possible to reduce damage to a specimen to be observed in acquisition of a diffraction pattern for adjusting an orientation of the specimen. Problems, configurations, and effects other than those described above will be clarified by description of the following embodiments.

### BRIEF DESCRIPTION OF DRAWINGS

FIG. 1 is a view showing an example of a configuration of a scanning transmission electron microscope (STEM) according to an embodiment of the present description.

FIG. 2 is a flowchart showing a processing outline.

FIG. 3A is an observation image schematically showing an example of an overall external appearance including a semiconductor specimen and a support structure of the semiconductor specimen.

FIG. 3B is a partially enlarged view showing an observation image of a semiconductor slice specimen.

FIG. 4 shows an example of a diffraction pattern acquired by illuminating a single crystal region with an electron beam.

FIG. 5 shows an example of a diffraction pattern acquired by illuminating a non-single crystal region with an electron beam.

FIG. 6 shows an example of a single crystal region, a non-single crystal region, and a non-transmissive region of an electron beam that are determined based on a diffraction pattern in the observation image shown in FIG. 3A.

FIG. 7 is a flowchart showing an example of processing of determining a boundary of a single crystal region.

FIG. 8 shows an example of a search region.

FIG. 9 shows an example of a search region.

FIG. 10 shows an example of a configuration of specimen information stored in a storage device by a control unit.

FIG. 11 is a flowchart showing an example of specimen orientation adjustment processing.

### DESCRIPTION OF EMBODIMENTS

Hereinafter, an embodiment of the invention will be described with reference to the drawings. However, the invention is not to be construed as being limited to the description of the following embodiment. It will be easily understood by those skilled in the art that a specific configuration can be changed without departing from the spirit or scope of the invention.

In configurations of the invention to be described below, the same or similar configurations or functions are denoted by the same reference numerals, and redundant description will be omitted.

Notations “first”, “second”, “third”, and the like in the present description and the like are provided to identify components, and do not necessarily limit the number or the order.

In order to facilitate understanding of the invention, a position, a size, a shape, a range, and the like of each configuration shown in the drawings and the like may not represent an actual position, size, shape, range, and the like. Therefore, the invention is not limited to the position, the size, the shape, the range, and the like disclosed in the drawings.

In a charged particle beam device according to an embodiment of the present description, when a diffraction pattern for adjusting an orientation of a specimen to be observed is to be acquired, an illumination position is not fixed and an illumination region is widened by scanning a minute region with a charged particle beam (a primary beam or simply referred to as a beam). Dispersion of the illumination position reduces damage and contamination caused by a temperature rise or the like. Further, since information is averagely acquired due to dispersion of regions, it is possible to adjust an orientation more accurately. The diffraction pattern includes a spot pattern and Ronchigram.

The charged particle beam device determines a scanning region of the charged particle beam according to a target specimen. The scanning region is, for example, a single crystal region. For example, when the specimen is a semiconductor chip, a region in a silicon substrate can be selected as the scanning region. The charged particle beam device can acquire a fixed (the same) diffraction pattern even when the single crystal region is scanned with a beam. A deflected specimen can be adjusted to an average orientation.

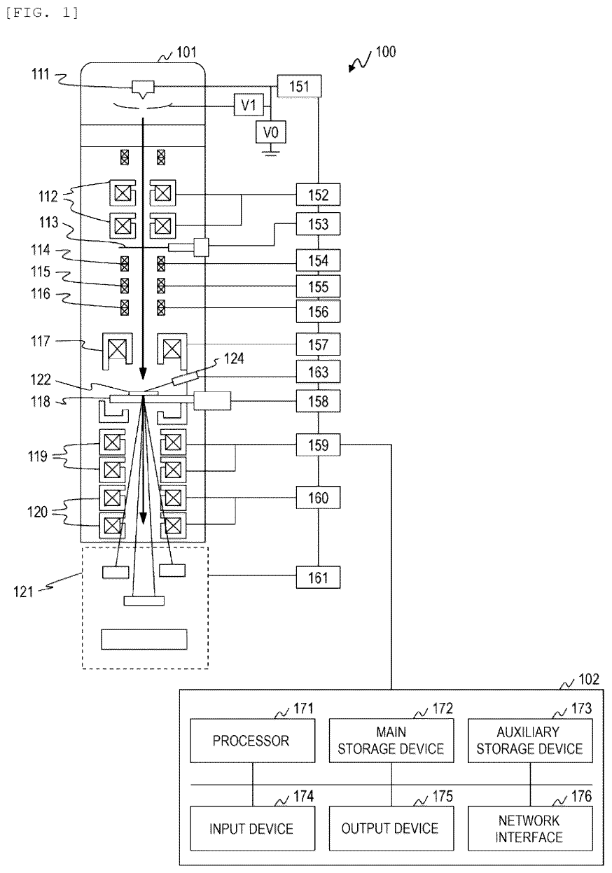

FIG. 1 is a view showing an example of a configuration of a scanning transmission electron microscope (STEM) according to an embodiment of the present description.

A STEM 100 includes an electron optical system column 101 and a control unit 102. The electron optical system column 101 includes an electron source 111, first and second condenser lens 112, a condenser aperture 113, an axial deviation correction deflector 114, a stigmator 115, an image shift deflector 116, an objective lens 117, a specimen stage 118, an intermediate lens 119, a projection lens 120, an electron detector group 121, and a secondary electron detector 124. When the devices included in the electron optical system column 101 are not distinguished from one another, the devices are also referred to as target devices.

The specimen stage 118 holds a specimen 122. The specimen 122 may be held by a specimen holder fixed to the specimen stage 118. The specimen stage 118 or the specimen holder or a combination of the specimen stage 118 and the specimen holder is an example of a movement mechanism that holds and moves the specimen 122. The specimen stage 118 can be tilted at one or more tilt axes (rotation axes).

An electron beam emitted from the electron source 111 which is a particle source is reduced by the first and the second condenser lenses 112, and a radiation angle is limited by the condenser aperture 113. Further, after an axis of the electron beam is adjusted by the axial deviation correction deflector 114, the stigmator 115, and the image shift deflector 116, the electron beam is emitted in an orientation substantially perpendicular to the specimen 122 by a specimen front side magnetic field of the objective lens 117.

The first and the second condenser lens 112, the condenser aperture 113, the axial deviation correction deflector 114, the stigmator 115, the image shift deflector 116, the objective lens 117, the specimen stage 118, the intermediate lens 119, and the projection lens 120 are examples of an optical element that adjusts an orientation and a focus of the electron beam on the specimen 122.

The control unit 102 is a controller, generates a secondary electron image indicating a surface structure of the specimen 122 based on secondary electrons detected by the secondary electron detector 124, and displays the secondary electron image to a user. Generally, in the STEM 100, a diffraction pattern is formed near a rear focus plane positioned between the objective lens 117 and the intermediate lens 119 due to an influence of a rear magnetic field of the objective lens 117. The diffraction pattern is detected by the electron detector group 121 (hereinafter, also simply referred to as the detector 121). The detector 121 may include an annular dark field-of-view detector, a bright field-of-view detector, a CCD camera, and the like. The detector 121 detects a signal emitted from the specimen 122 illuminated with the electron beam.

A computer serving as the control unit 102 controls the electron optical system column 101 using a plurality of control circuits. The control unit 102 includes an electron gun control circuit 151, an illumination lens control circuit 152, a condenser aperture control circuit 153, an axial deviation correction deflector control circuit 154, a stigmator control circuit 155, an image shift deflector control circuit 156, an objective lens control circuit 157, a specimen stage control circuit 158, an intermediate lens control circuit 159, a projection lens control circuit 160, a transmission scattering detector control circuit 161, and a secondary electron detector control circuit 163.

The control unit 102 acquires a value of each target device via each control circuit, and creates any electron optical condition by inputting the value to each target device via each control circuit. The control unit 102 is an example of a control mechanism that controls the electron optical system column 101.

The control unit 102 includes a processor 171, a main storage device 172, an auxiliary storage device 173, an input device 174, an output device 175, and a network interface 176. These devices are connected to one another via a bus.

The processor 171 executes a program stored in the main storage device 172. The processor 171 functions as various functional units by executing processing according to programs.

The main storage device 172 is a storage device such as a semiconductor memory, and stores a program and data executed by the processor 171. The main storage device 172 is also used as a work area for temporary use of programs. The main storage device 172 stores, for example, an operating system, a program for controlling a target device of the STEM 100, a program for acquiring an image of the specimen 122, and a program for processing the acquired image.

In the present description, when processing is described using the STEM 100 (the control unit 102) as a subject, it indicates that the processor 171 that executes any one of the programs is executing the processing.

The auxiliary storage device 173 is a storage device such as a hard disk drive (HDD), a solid state drive (SSD), or the like, and permanently stores data. A program and data stored in the main storage device 172 may be stored in the auxiliary storage device 173. In this case, when the control unit 102 is start up or when processing is required, the processor 171 reads a program and data from the auxiliary storage device 173 and loads the program and the data into the main storage device 172.

The input device 174 is a device for a user to input instructions and information to the control unit 102, such as a keyboard, a mouse, and a touch panel. The output device 175 is a device for outputting an image, an analysis result, and the like to a user, such as a display and a printer. The network interface 176 is an interface for performing communication via a network.

Although the control unit 102 is described as a computer in FIG. 1, the control unit 102 may be implemented using a plurality of computers. Some functions of the control unit 102 may be implemented by using a logic circuit such as an ASIC or an FPGA that is configured for specific processing. Primary charged particles emitted to the specimen 122 may be different from electrons.

The STEM 1 illuminates the specimen 122 with a converged electron beam, and scans the specimen 122 with the converged electron beam using a deflection coil such as the image shift deflector 116. The detector 121 records a signal detected by the detector at each scanning position on the specimen, and the control unit 102 displays an image. The detector 121 may include a plurality of types of detectors such as an annular dark field-of-view detector, an annular bright field-of-view detector, a bright field-of-view detector, and a CCD camera. A desired type of image can be acquired by detecting transmitted or scattered electron by a detector selected according to lens adjustment below the specimen.

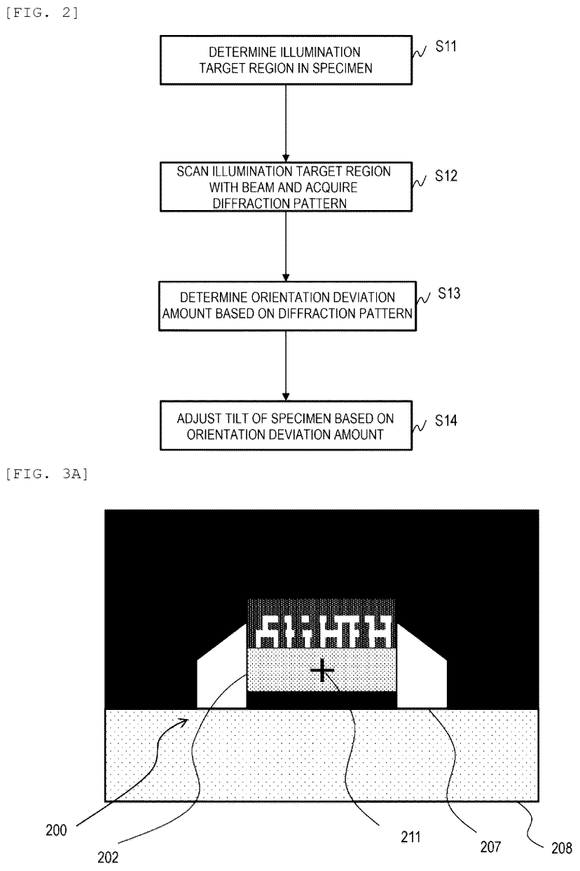

FIG. 2 is a flowchart showing an outline of processing executed by the STEM 1. The STEM 1 automatically adjusts the specimen stage 118 so that deviation between an orientation of the specimen 122 and an incident orientation of an electron beam to the specimen 122 is minimized.

When the specimen 122 is observed by the STEM, a length measurement can be performed with high accuracy by matching an electron beam incident orientation and a specimen orientation at the time of observation. When the specimen orientation deviates from the electron beam incident orientation, an interface is blurred and accuracy of the length measurement is reduced. The specimen orientation is adjusted using a diffraction pattern formed by the electron beam transmitted through the specimen 122. The STEM 1 changes tilt of the specimen while measuring a deviation amount of the specimen orientation based on the diffraction pattern.

In order to acquire the diffraction pattern, the STEM 1 scans a specific region of the specimen 122 with the electron beam. When the diffraction pattern for orientation adjustment is acquired, an illumination region is widened by performing scanning with the electron beam in a target region, and damage and contamination of the specimen 122 can be reduced.

In an embodiment of the present description, a single crystal region (hereinafter, simply referred to as a crystal region) in the specimen 122 is selected as a target region for acquiring a diffraction pattern. For example, in a semiconductor device, n substrate is generally formed of single crystal silicon, and has a sufficient width for reducing damage. In an example to be described below, the STEM 1 scans a region in the silicon substrate of the specimen 122 with an electron beam to acquire a diffraction pattern.

Referring to FIG. 2, the control unit 102 determines an illumination target region for acquiring a diffraction pattern in the specimen 122 (S11). Details of a method for specifying the illumination target region will be described later. Next, the control unit 102 scans the illumination target region determined in step S11 with an electron beam to acquire a diffraction pattern (S12).

Next, the control unit 102 determines a deviation amount of an orientation of the specimen 122 from an electron beam incident orientation based on the diffraction pattern (S13). Further, the control unit 102 controls the specimen stage 118 to adjust tilt of the specimen 122 based on the orientation deviation amount determined in step S103 (S14). Accordingly, a crystal orientation of the specimen can be aligned with an incidence angle of the electron beam, and the deviation can be minimized. If possible, the incidence angle of the electron beam may be adjusted instead of controlling the tilt of the specimen.

Hereinafter, the method (S11) for determining the illumination target region for acquiring a diffraction pattern for orientation adjustment in the specimen 122 will be described. Here, the control unit 102 selects a single crystal region as the illumination target region. Any region in the specimen 122 where a diffraction pattern can be acquired can be selected as the illumination target region.

A region to be specified as the illumination target region and a specifying method of the illumination target region are specified for each specimen 122, and the STEM 1 determines the illumination target region according to the specimen 122. In one embodiment, the control unit 102 may refer to specimen information including specimen structure information and determine a region having a size and a shape indicated by the specimen information as the illumination target region. In one embodiment, the control unit 102 may refer to a signal acquired by illuminating the specimen 122 with an electron beam and determine a region of a specified substance state as the illumination target region. An example of the specified substance state is a single crystal structure.

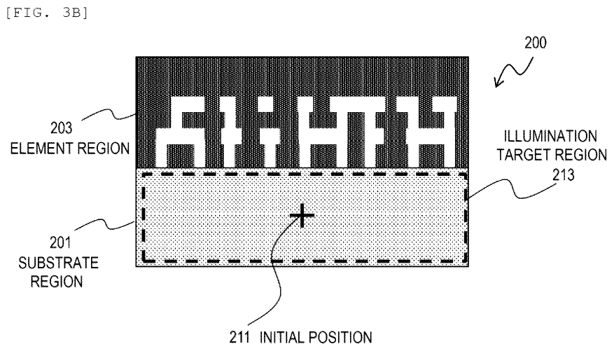

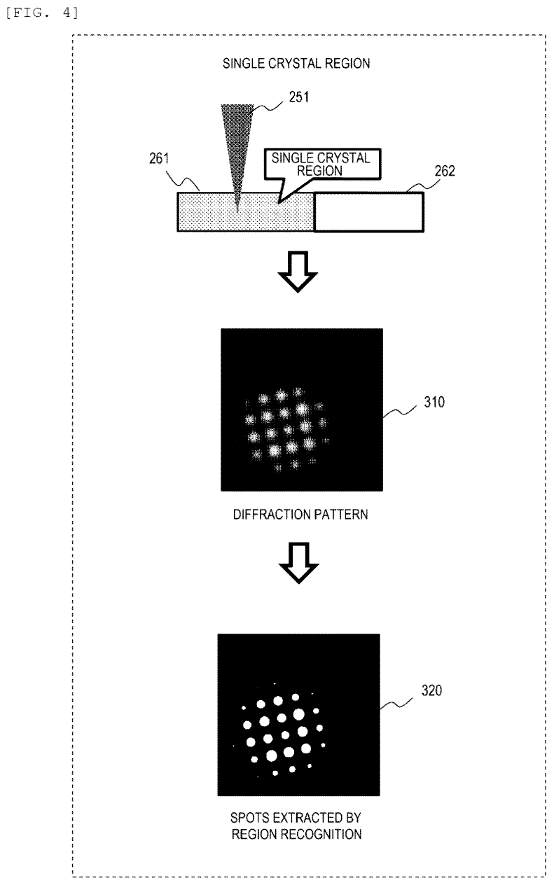

FIG. 3A is an observation image schematically showing an example of an overall external appearance including a semiconductor specimen and a support structure of the semiconductor specimen. FIG. 3A shows a secondary electron image. In FIG. 3A, the semiconductor specimen 200 includes a rectangular slice region 202 and support portions 207 (only one of the support portions is indicated by a reference numeral) on both sides. The support portion 207 is coupled to a base portion 208 on a lower side in FIG. 3A. In FIG. 3A, the slice region 202 is, for example, a region of the semiconductor specimen 200 that is sliced by being illuminated with a converged ion beam from an orientation of an upper side of the drawing. The support portion 207 is a region that is not sliced and has a thickness. The base portion 208 is also a region having a thickness.

Since the electron beam is transmitted through the slice region 202 of the semiconductor specimen 200, the slice region 202 is an observable region. The observable region is a region in the specimen where the electron beam is transmitted (including straight electrons and scattered electrons). On the other hand, the support portion 207 and the base portion 208 having a thickness cannot let the electron beam transmit and are unobservable regions. Other regions in FIG. 3A are spaces (vacuum regions) where no substance is present. The electron beam is not scattered in the vacuum regions and is transmitted. The vacuum region is an observable region, and is a non-single crystal region (also simply referred to as a non-crystal region) to be described later in the present description. Hereinafter, the slice region of the semiconductor specimen is also referred to as a semiconductor slice specimen.

The control unit 102 acquires a secondary electron observation image or a STEM observation image of the specimen 200. For example, the specimen stage 118 is moved by pattern matching so that an initial position (an initial illumination position) 211 is located near the center of the field of view. FIG. 3B is a partially enlarged view showing an observation image of the semiconductor slice specimen 202. The semiconductor slice specimen (the observable region) 202 includes a substrate region 201 made of single crystal silicon and an element region (a structure region) 203 on the substrate region 201. The element region 203 is a non-single crystal region. In the present example, the initial position 211 is located substantially at the center of the substrate region 201.

The control unit 102 determines an illumination target region 213 in the substrate region 201. The control unit 102 acquires a diffraction pattern while scanning the specimen. The control unit 102 searches for a region where the diffraction pattern does not change from the initial position 211, and determines the region as the illumination target region 213.

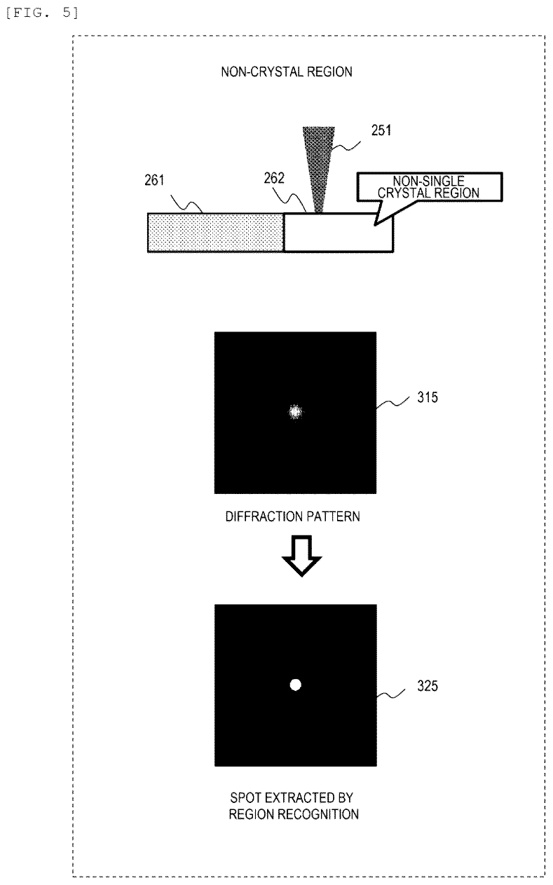

FIG. 4 shows an example of a diffraction pattern acquired by emitting an electron beam to a single crystal region. The specimen includes a single crystal region 261 and a non-single crystal region 262. An electron beam 251 is emitted to the single crystal region 261. The same diffraction pattern can be acquired regardless of an illumination position in the single crystal region 261. An acquired diffraction pattern 310 includes a plurality of spots arranged regularly in a two-dimensional manner. By performing region recognition (a blob analysis or the like) of the diffraction pattern 310, a diffraction pattern 320 in which each spot can be clearly determined is acquired. In the blob analysis, the diffraction pattern 310 is binarized to determine an outer shape of each spot.

FIG. 5 shows an example of a diffraction pattern acquired by emitting an electron beam to a non-single crystal region. The electron beam 251 is emitted to the non-single crystal region 262. An acquired diffraction pattern 315 includes one spot. By performing region recognition (a blob analysis) of the diffraction pattern 315, a diffraction pattern 325 in which the spot can be clearly determined is acquired. In the blob analysis, the diffraction pattern 315 is binarized to determine an outer shape of each spot.

As shown in FIGS. 4 and 5, the diffraction pattern 310 of the single crystal region and the diffraction pattern 315 of the non-single crystal region have different pattern shapes. The pattern acquired from the single crystal region includes a plurality of periodic diffraction spots corresponding to a crystal structure. The pattern acquired from the non-single crystal region includes only one spot through which the beam is transmitted.

As described above, the control unit 102 acquires a list indicating coordinates, a size, and the like of each spot by performing the binarization processing and the blob analysis. The control unit 102 may determine the illumination target region by evaluating the number of diffraction spots for a diffraction pattern acquired at an illumination position to be evaluated. For example, when the number of spots in a pattern is less than one or less than a reference number, the control unit 102 can determine a region as the non-single crystal region. When the number of spots is larger than a reference number, the control unit 102 can determine a region as the single crystal region.

In another example, the control unit 102 can detect a boundary between the single crystal region 261 and the non-single crystal region 262 by moving an illumination position of the electron beam and comparing a diffraction pattern acquired at each position with a diffraction pattern acquired at an initial position. For example, the single crystal region 261 and the non-single crystal region 262 can be distinguished by comparing a position, a size, the number, or the like of each spot in a diffraction pattern acquired by performing the blob analysis on the diffraction pattern acquired at each position and the diffraction pattern acquired at the initial position.

The control unit 102 may evaluate similarity between the diffraction pattern acquired at the initial position which is a reference illumination position and a diffraction pattern acquired at an illumination position to be evaluated. The control unit 102 calculates the similarity between the two diffraction patterns, and determines a position where the similarity is a threshold as a boundary between illumination target regions.

The similarity between the two patterns can be calculated, for example, based on match or mismatch of luminance values of pixels of the diffraction patterns. When the total number of pixels whose luminance value difference exceeds a predetermined reference is smaller than a threshold, it may be determined that two diffraction patterns similar. A method for calculating the similarity between diffraction patterns can be determined appropriately by design. The blob analysis enables a more accurate comparison, but may be omitted.

FIGS. 4 and 5 show diffraction patterns including a plurality of spots arranged in a two-dimensional manner. Such diffraction patterns are acquired on a diffraction plane by illuminating a specimen with a parallel electron beam. As another example of a diffraction pattern, Ronchigram can be used. Ronchigram is a diffraction pattern that can be formed on a diffraction plane when a beam emitted to a specimen is converged.

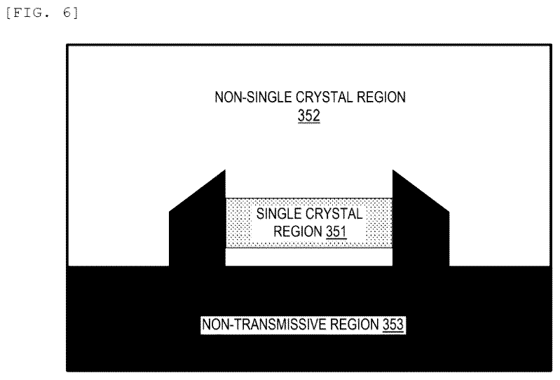

FIG. 6 shows an example of a single crystal region, a non-single crystal region, and a non-transmissive region of an electron beam that are determined based on a diffraction pattern in the observation image shown in FIG. 3A. A single crystal region 351 coincides with the substrate region (a single crystal region) 201 shown in FIG. 3B. A non-transmissive region 353 coincides with a region of the support portion 207 and the base portion 208 shown in FIG. 3A. A non-single crystal region 352 includes the element region 203 shown in FIG. 3B and the vacuum region shown in FIG. 3A.

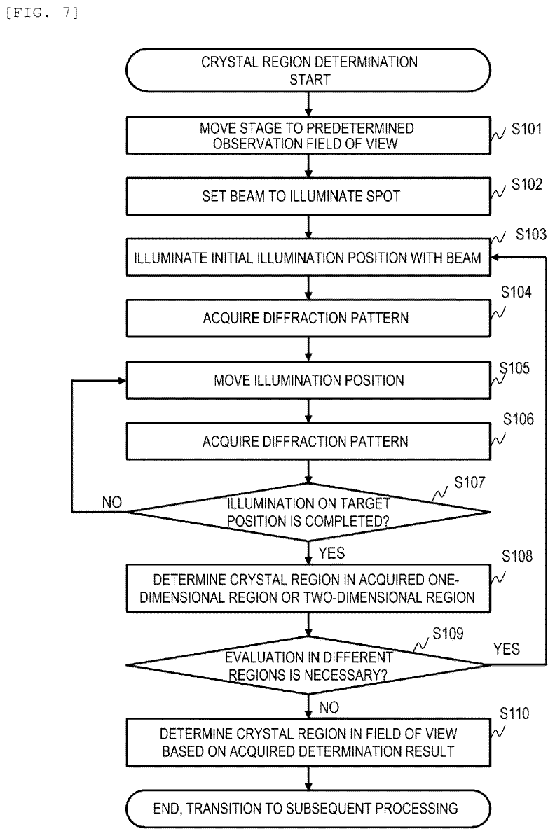

FIG. 7 is a flowchart showing an example of processing of determining a boundary of a single crystal region. In the present example, as described above, the control unit 102 determines a single crystal region based on a diffraction pattern of a specimen.

First, the control unit 102 moves the stage 118 to a predetermined observation field of view (S101). At this time, the control unit 102 scans a specimen with an electron beam to acquire an observation image of the specimen by secondary electrons. Depending on the specimen, a bright field-of-view image or a dark field-of-view image may be used instead of a secondary electron image. The control unit 102 moves the stage 118 so that the specimen is positioned at a predetermined position in the observation field of view by matching with a pattern held in advance. The control unit 102 determines an initial illumination position for aligning specimen orientation in a single crystal region (a substrate region). The initial illumination position may be specified in advance in a pattern.

Next, the control unit 102 sets the electron beam to illuminate a spot (S102), and illuminates the initial position with the electron beam (S103). The control unit 102 acquires a diffraction pattern at the initial position and stores the diffraction pattern in a storage device (S104).

Next, the control unit 102 moves the illumination position of the electron beam (S105), acquires a new diffraction pattern, and stores the new diffraction pattern in the storage device (S106). A moving orientation and a moving distance may be determined based on preset control information. Details will be described later.

The control unit 102 determines whether a current illumination position is a last illumination target position in a current search region (S107). For example, one or more one-dimensional or two-dimensional search regions for searching for an illumination target region may be set. For example, a position and a shape (a size) of the search region are specified with reference to the initial position. The control unit 102 sequentially emits spot-shaped electron beams at different positions in specified search regions to acquire diffraction patterns. When the illumination position reaches an end of the current search region, it is determined that the illumination position is a last illumination target position.

Next, the control unit 102 determines a single crystal region in the acquired one-dimensional or two-dimensional region (S108). In a method for determining the single crystal region, for example, similarity between a diffraction pattern acquired at the initial position and each of the acquired diffraction patterns is calculated, and it is determined that a position at which the similarity exceeds a threshold is a boundary of the single crystal region.

Next, the control unit 102 determines whether evaluation in different regions is necessary (S109). When evaluation of all pre-specified search regions is completed, the evaluation in different regions is unnecessary (S109: NO). When there is an unevaluated region, it is necessary to evaluate the region (S109: YES).

When there is an unevaluated region (S109: YES), the control unit 102 returns the processing to step S103. When evaluation of all the search regions is completed (S109: NO), the control unit 102 determines a single crystal region in the field of view based on a determination result acquired in step S108 (S110).

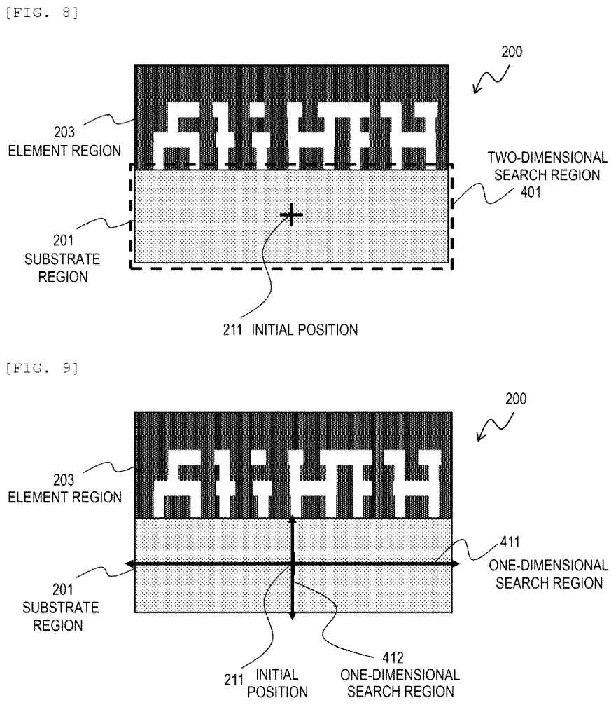

FIG. 8 shows an example of a search region. In the example shown in FIG. 8, one two-dimensional search region 401 is specified. The two-dimensional search region 401 has a rectangle shape including the substrate region 201 with an initial position as a center. The control unit 102 scans the two-dimensional search region 401 with an electron beam to acquire a diffraction pattern at each illumination position.

For example, the control unit 102 moves the illumination position of the electron beam at a constant pitch from a left end to a right end of the two-dimensional search region 401, and acquires a diffraction pattern at each movement destination. When the illumination position reaches the right end, the control unit 102 moves the electron beam to a position away from a previous illumination position at the left end of the two-dimensional search region 401 by a predetermined distance. The control unit 102 repeats the above processing to acquire diffraction patterns in the entire two-dimensional search region 401.

The search region may have any shape including the initial position. For example, the search region and a region of the observation field of view may coincide with each other.

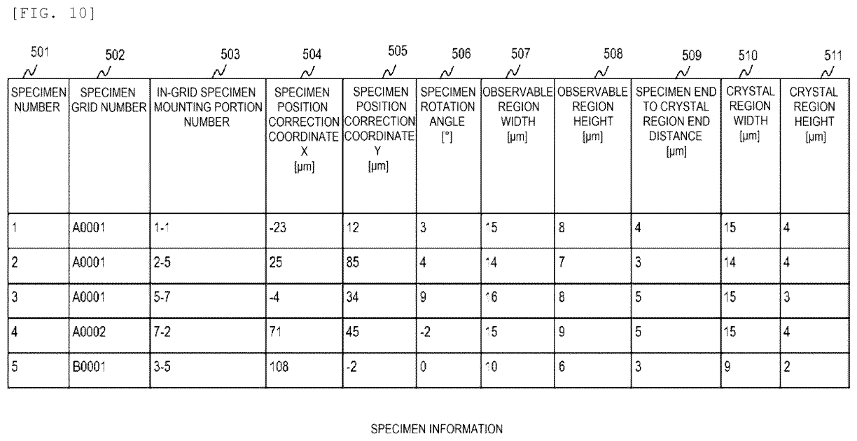

FIG. 9 shows an example of a search region. In the example shown in FIG. 9, two one-dimensional search regions 411 and 412 are specified. In the example shown in FIG. 9, the one-dimensional search region 411 is a straight line (an axis) that passes through the initial position 211 and extends in a left-right orientation. The one-dimensional search region 412 is a straight line (an axis) that passes through the initial position 211 and extends in an up-down orientation. An angle formed by the one-dimensional search region 411 and the one-dimensional search region 412 is a right angle.

In the example shown in FIG. 9, the substrate region 201 which is a single crystal region has a long square shape (including a regular square shape). The one-dimensional search region 411 is parallel to one side of the substrate region 201, and the one-dimensional search region 412 is parallel to a side adjacent to the one side. Therefore, a boundary of a single crystal region can be estimated from four single crystal region boundary positions on the one-dimensional search regions 411 and 412. Although the two one-dimensional search regions are not parallel, the angle between the two one-dimensional search regions may not be a right angle. The one-dimensional search regions may not pass through the initial position.

For example, the control unit 102 acquires diffraction patterns at a plurality of points of the one-dimensional search region 411, determines a single crystal region, and then acquires diffraction patterns at a plurality of points of the one-dimensional search region 412, and determines a single crystal region.

First, the control unit 102 moves an electron beam in a right orientation from the initial position 211 at a constant pitch on the one-dimensional search region 411, and acquires a diffraction pattern at each position. Thereafter, the control unit 102 moves the electron beam in a left orientation from the initial position 211 at a constant pitch on the one-dimensional search region 411, and acquires a diffraction pattern at each position. The movement on the one-dimensional search region 411 is not necessarily started from the initial position 211, and the electron beam may be moved at a constant pitch from one end of the one-dimensional search region 411 toward the other end. The control unit 102 identifies a boundary position of a single crystal region on the one-dimensional search region 411 by analyzing diffraction patterns.

Next, the control unit 102 moves the electron beam in an up orientation from the initial position 211 at a constant pitch on the one-dimensional search region 412, and acquires a diffraction pattern at each position. Thereafter, the control unit 102 moves the electron beam in a down orientation from the initial position 211 at a constant pitch on the one-dimensional search region 412, and acquires a diffraction pattern at each position. The movement on the one-dimensional search region 412 is not necessarily started from the initial position 211, and the electron beam may be moved at a constant pitch from one end of the one-dimensional search region 412 to the other end. The control unit 102 identifies a boundary position of a single crystal region on the one-dimensional search region 412 by analyzing diffraction patterns.

In an embodiment of the present description, the control unit 102 may identify the boundary of the single crystal region without referring to a specified search region. The control unit 102 compares a diffraction pattern at an initial position with a newly acquired diffraction pattern every time a diffraction pattern at one or more illumination positions is acquired on a one-dimensional search region. The control unit 102 determines a position where similarity is less than a threshold as a boundary position of a single crystal region on the one-dimensional search region.

The control unit 102 performs the same processing in a plurality of one-dimensional search regions extending radially from the initial position. The single crystal region can be identified by connecting boundary positions of the single crystal region of all one-dimensional search regions.

Another example of the method for determining an illumination target region for acquiring a diffraction pattern for specimen orientation adjustment will be described below. In an embodiment of the present description, the control unit 102 may determine an illumination target position using a plurality of scanning transmission microscope images acquired by using signal components of different scattering angles. Examples of the plurality of scanning transmission microscope images include a bright field-of-view image (a bright field-of-view signal) and a dark field-of-view image (a dark field-of-view signal) of a specimen. An observation image can be acquired in a shorter time than a diffraction pattern.

Since an electron beam is strongly diffracted in a single crystal region, an electron beam intensity on an axis (a zero order) decreases and an electron beam intensity around the axis increases. An on-axis intensity roughly corresponds to a bright field-of-view signal intensity and a surrounding intensity corresponds to a dark field-of-view signal intensity. The bright field-of-view image and the dark field-of-view image have a complementary relationship. A combined intensity of the two images can be approximately considered to be a constant value.

The control unit 102 generates an image indicating a comparison result between the bright field-of-view image and the dark field-of-view image. A comparison result image can be generated using, for example, a difference value between a luminance value of each pixel of the bright field-of-view image and a luminance value (an intensity value) of each pixel of the dark field-of-view image. The control unit 102 performs an image analysis on the generated difference image to identify a single crystal region having the same structure (including a crystal orientation) as that at the initial position. Any method of image analysis may be used, and a region that is a continuous region including the initial position and is configured with pixels with luminance in a predetermined range from luminance at the initial position may be determined as a single crystal region.

In another example, the control unit 102 may independently refer to the bright field-of-view image and the dark field-of-view image. In both the bright field-of-view image and the dark field-of-view image, a region determined as a single crystal region according to luminance of the pixels as described above may be determined as a single crystal region of the specimen.

In an embodiment of the present description, the control unit 102 determines an illumination target region based on signals from different divided regions of a detector. Accordingly, high-speed processing can be executed. For example, an annular dark field-of-view detector can be divided into a plurality of regions in a circumferential orientation and a radial orientation. The different divided regions detect scattered electron components having different scattering orientations or scattering angles. For example, the control unit 102 calculates a difference between signals detected by different regions of the detector. Since a diffraction pattern formed on the detector greatly differs between a single crystal region and a non-single crystal region or a region having another crystal orientation, a signal amount acquired in each divided detection region changes greatly. Therefore, a difference between signals detected by different regions of the detector greatly differs between the single crystal region and other regions. In addition, a region can be determined by using a ratio, a product, or the like of signals.

The control unit 102 may determine, as the single crystal region, a region that is a continuous region including the initial position and in which a difference between detection signals at a certain position falls within a predetermined difference range relative to a difference between detection signals at the initial illumination position. A position where a difference changes beyond a threshold is determined as a boundary between the single crystal region and the non-single crystal region.

In an embodiment of the present description, after an initial position of a specimen to be measured is determined, the control unit 102 may determine an illumination target region based on specimen information that is stored in advance, regardless of a detection signal of the specimen. For example, the control unit 102 stores information that defines a position and a shape of the illumination target region and determines a region indicated by the information as the illumination target region with reference to the initial position.

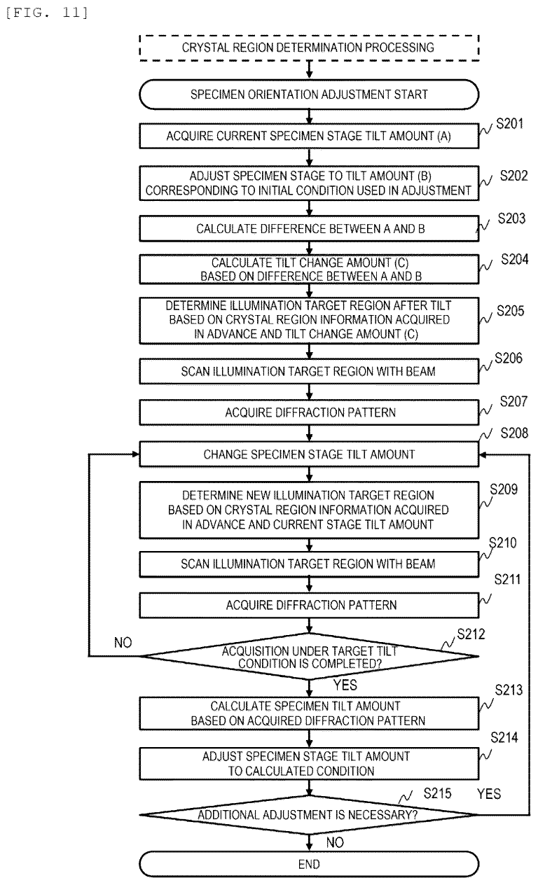

FIG. 10 shows a configuration example of specimen information stored in a storage device by the control unit 102. The specimen information manages information about a specimen to be observed. The control unit 102 can refer to the specimen information to adjust an orientation of the specimen.

The example of the specimen information shown in FIG. 10 has a table structure including a plurality of columns 501 to 511. The specimen number column 501 indicates a number for identifying a specimen to be measured, and a specimen grid number column 502 indicates a number for identifying a grid on which the specimen is placed.

The in-grid specimen mounting portion number column 503 indicates a number corresponding to a place where the specimen is mounted on a specimen grid. The number described above indicates a number of a specimen mounting protrusion having a semicircular mesh shape and a number (an address) of coordinates in the protrusion, or coordinates on a mesh in which regions are provided in a grid pattern. When a mounting portion number is determined, it is determined which address (X: ˜μm, Y: ˜μm) on the grid a specimen is mounted. In addition, depending on how the specimen is mounted, a position of the specimen may be slightly deviated from a reference position at each address.

A specimen position correction coordinate X column 504 and a specimen position correction coordinate Y column 505 indicates a deviation amount of a specimen mounting portion from a reference position. A specimen rotation angle column 506 indicates an angle at which the specimen is tilted relative to a horizontal reference in a grid. The specimen rotation angle column 506 shows an angle (a rotation amount in a plane) for correcting (rotating) an illumination orientation of a beam at the time of observation. Tilt amounts of a specimen stage on an α axis and a β axis are angles in an orientation orthogonal to the plane, and are different from a specimen rotation angle.

An observable region width column and an observable region height column 508 respectively indicate a width and a height of an observable region of the specimen. The observable region is a sliced region in the specimen, let an electron beam transmit, and can be observed. In the example shown in FIG. 3A, the slice region 202 is an observable region.

A specimen end to crystal region end distance column 509 indicates a distance from a specimen end to a crystal region end (a single crystal region end). A crystal region width column 510 indicates a width of a crystal region (a single crystal region) including an initial position in the specimen. A crystal region height column 511 indicates a height of a crystal region (a single crystal region) including the initial position in the specimen.

Parameters indicated by the column 507 to the column 511 have the following relationship.

$$observable region width = single crystal region width$$

$$observable region height = specimen end to single crystal region end distance + single crystal region height$$

After the control unit 102 aligns the specimen in the observation field of view and identifies the initial position, the control unit 102 may determine an illumination target region for acquiring a diffraction pattern for orientation adjustment based on the initial position and the specimen information. For example, the initial position is at the center of a single crystal region, and an illumination target region is determined based on a single crystal region indicated by the specimen information. For example, a region may be determined as an inner region by a predetermined numerical value in the single crystal region. Alternatively, a predetermined size is determined in advance for an illumination target region, and when it can be determined based on the specimen information that the single crystal region in the specimen is not smaller than the predetermined size, a region of the predetermined size may be illuminated.

The specimen information may be referred to when determining the search region described with reference to FIG. 8 or FIG. 9. For example, in the example shown in FIG. 8, the initial position is at the center of the single crystal region, and the two-dimensional search region 401 may be determined as a region that includes the single crystal region indicated by the specimen information and is larger than the single crystal region by a predetermined size. In the example shown in FIG. 9, the one-dimensional search regions 411 and 412 are determined according to a height and a width of the single crystal region, and, for example, may be set to be longer by a predetermined number.

Specimen orientation adjustment processing will be described below. FIG. 11 is a flowchart showing an example of the specimen orientation adjustment processing. The specimen orientation adjustment processing is executed after the illumination target region for acquiring a diffraction pattern is determined.

First, in step S201, the control unit 102 acquires a current specimen stage tilt amount (A). The specimen stage tilt amount can be expressed by, for example, tilt angles at two different axes of the x axis and the B axis.

Next, in step S202, the control unit 102 adjusts the specimen stage to a tilt amount (B) corresponding to an initial condition used in an adjustment. The initial condition is set in advance in the control unit 102.

Next, in step S203, the control unit 102 calculates a difference between the specimen stage tilt amount (A) and the specimen stage tilt amount (B). Further, in step S204, the control unit 102 calculates a tilt change amount (C) based on the difference.

In step S205, the control unit 102 determines an illumination target region after the tilt based on information on the single crystal region acquired in advance and the tilt change amount (C). The information on the single crystal region acquired in advance is indicated in the single crystal region width column 510 and the single crystal region height column 511 in the specimen information described with reference to FIG. 10.

When the specimen is tilted, an apparent area of the single crystal region as viewed from an observation orientation (an axial orientation in which a primary beam is emitted) changes. When a normal line of the single crystal region coincides with the observation orientation, an observed single crystal region and an actual single crystal region coincide with each other. However, when the single crystal region is tilted relative to the observation orientation, a shape of the single crystal region viewed in the observation orientation changes to a shape (a size) corresponding to a tilt angle. In step S205, an illumination target region of a primary electron beam that changes according to an angle of the specimen is determined.

Next, in step 206, the control unit 102 scans the illumination target region determined in step S205 with the electron beam. In step S207, the control unit 102 acquires a diffraction pattern of the illumination target region.

Next, in step S208, the control unit 102 changes the specimen stage tilt amount. A change orientation and a change amount follow a predetermined setting. In step S209, the control unit 102 determines a new illumination target region based on the single crystal region information acquired in advance and a current stage tilt amount. The processing in this step is the same as that in step S205.

Next, in step 210, the control unit 102 scans the illumination target region determined in step S209 with the electron beam. In step S211, the control unit 102 acquires a diffraction pattern of the illumination target region.

In step S212, the control unit 102 determines whether acquisition under all target tilt conditions is completed. When there is an unmeasured tilt condition (S212: NO), the flow returns to step S208. When measurement under all tilt conditions is completed (S212: YES), the flow proceeds to step S213.

In step S213, the control unit 102 calculates an optimum tilt amount of the specimen for specimen measurement based on diffraction patterns acquired at different tilt angles. Further, in step S214, the control unit 102 adjusts the specimen stage tilt amount to a calculated condition. When an additional adjustment is not necessary (S215: NO), the control unit 102 ends this flow. When an additional adjustment is necessary, the flow returns to step S208.

As described above, the control unit 102 moves an illumination position of the electron beam in the illumination target region and acquires diffraction patterns according to a detection result of a detector at different illumination positions. The control unit 102 controls the specimen stage 108 based on an analysis result of the diffraction patterns to adjust tilt of the specimen. There is a method for acquiring a diffraction pattern. In one method, the detector 121 continuously detects a signal from the specimen while moving the illumination position of the electron beam, and generates diffraction patterns. One diffraction pattern is generated from a signal that is continuously detected.

In another method, the control unit 102 generates a diffraction pattern from diffraction patterns of detection signals of the detector 121 at different illumination positions. For example, the control unit 102 generates a new diffraction pattern by summing up or averaging a plurality of diffraction patterns acquired by the detector 121 at different illumination positions of the electron beam.

As described above, in step S213, the control unit 102 determines an optimum specimen orientation based on diffraction patterns acquired at different tilt angles. Various methods for determining an optimum specimen orientation are known, and the control unit 102 may use any one of the methods. The optimum specimen orientation can be determined by the following methods.

For example, the control unit 102 acquires diffraction patterns under a plurality of conditions in which a specimen tilt angle is changed, and controls an angle of the specimen stage 118 based on a position of a spot included in a diffraction pattern. For example, the control unit 102 fits a circle on a spot group of each pattern, and measures a distance from the center of the circle to a center position of a diffraction pattern and an orientation. The control unit 102 can determine an appropriate tilt condition based on a change in measurement results relative to tilt angles. The control unit 102 may evaluate a correlation coefficient between a diffraction pattern acquired under each condition in which the specimen is tilted and a diffraction pattern (a reference) in a target orientation. An orientation in which a correlation value is the maximum can be determined as an optimum specimen orientation.

Another method is to use a Kikuchi pattern. In a transmission electron microscope (TEM), a plane in the vicinity of a focus of an objective lens that converges an emitted beam at one point is referred to as a diffraction plane, and a pattern formed on the diffraction plane is referred to as a diffraction pattern. In particular, a pattern that is formed into a diffraction plane when a beam emitted to the specimen is converged (non-parallel) is called Ronchigram. Ronchigram is a type of convergent beam electron diffraction pattern (a CBED Pattern). The diffraction pattern includes a spot-shaped pattern formed by converging a beam at one point, and Ronchigram.

The Kikuchi pattern is a linear pattern formed by a diffraction plane when a crystal material is illuminated with an electron beam. The Kikuchi pattern appears in a superimposed manner on any diffraction pattern of a spot-shaped pattern or Ronchigram.

The control unit 102 acquires a diffraction pattern including a plurality of Kikuchi lines, and controls an angle of the specimen stage 118 based on positions of the Kikuchi lines included in the diffraction pattern. For example, the control unit 102 calculates a crystal band axis of the specimen by performing an analysis based on a plurality of intersection points where two Kikuchi lines intersect with each other. The control unit 102 can calculate a tilt angle which is an angle at which the specimen is tilted based on the crystal band axis and an emission orientation of an electron beam.

For example, the control unit 102 can calculate a center and a radius of an inscribed circle for each of a plurality of triangular shapes formed by intersection points of the plurality of Kikuchi lines, and can calculate a crystal band axis of the specimen based on the center and the radius of the inscribed circle. In addition, the control unit 102 may calculate coordinates at which a sum of distances from the plurality of intersection points is the minimum as the crystal band axis of the specimen.

The invention is not limited to the embodiment described above, and includes various modifications. Contents described by taking a device configuration of an STEM as an example can also be implemented in a device configuration of a TEM. For example, the embodiment described above is described in detail to facilitate understanding of the invention, and the invention is not necessarily limited to those including all the described configurations. A part of a configuration in each embodiment may be added to, deleted from, or replaced with another configuration.

A part or all of the configurations, functions, processing units, processing methods, and the like described above may be implemented by hardware by, for example, designing with an integrated circuit. The invention can also be implemented by a program code of software for implementing functions of the embodiment. In this case, a storage medium storing the program code is provided to a computer, and a processor provided in the computer reads the program code stored in the storage medium. In this case, the program code read from the storage medium implements the functions of the embodiment described above, and the program code and the storage medium storing the program code implement the invention. Examples of the storage medium for supplying such a program code include a flexible disk, a CD-ROM, a DVD-ROM, a hard disk, a solid state drive (SSD), an optical disk, a magneto-optical disk, a CD-R, a magnetic tape, a nonvolatile memory card, and a ROM.

Further, the program code for implementing the functions described in the present embodiment can be implemented in a wide range of programs or script languages such as assembler, C/C++, Perl, Shell, PHP, Python, and Java.

Further, the program code of software for implementing the functions of the embodiment may be distributed via a network to be stored in a storage unit such as a hard disk or a memory of a computer or a storage medium such as a CD-RW or a CD-R, and a processor provided in the computer may read and execute the program code stored in the storage unit or the storage medium.

Control lines and information lines considered to be necessary for description are shown in the embodiment described above, and not all control lines and information lines in a product are necessarily illustrated. All components may be connected to one another.

1. A charged particle beam device comprising:
a movement mechanism configured to hold and move a specimen;
a particle source configured to output a charged particle beam;
a detector configured to detect a signal generated by illuminating the specimen with the charged particle beam; and
a controller configured to control the movement mechanism, the particle source, and the detector, wherein
the controller is configured to
determine an illumination target region in the specimen according to the specimen,
move an illumination position of the charged particle beam in the illumination target region, and acquire a diffraction pattern according to a detection result of the detector at different illumination positions, and
control the movement mechanism based on an analysis result of the diffraction pattern to adjust tilt of the specimen.

2. The charged particle beam device according to claim 1, wherein
the controller is configured to
store specimen information including information on a structure of the specimen in advance, and
determine the illumination target region based on the specimen information.

3. The charged particle beam device according to claim 1, wherein
the illumination target region is a single crystal region in the specimen, and
the controller is configured to determine the single crystal region based on a detection signal of the detector.

4. The charged particle beam device according to claim 1, wherein
the detector continuously detects the signal while the illumination position is moved to generate the diffraction pattern.

5. The charged particle beam device according to claim 1, wherein
the controller is configured to generate a diffraction pattern to be analyzed from diffraction patterns of detection signals at the different illumination positions.

6. The charged particle beam device according to claim 1, wherein
the controller is configured to control the movement mechanism based on a position of a spot included in the diffraction pattern.

7. The charged particle beam device according to claim 1, wherein
the controller is configured to control the movement mechanism based on a position of a Kikuchi line included in the diffraction pattern.

8. The charged particle beam device according to claim 1, wherein
the controller is configured to determine the illumination target region by evaluating similarity between a diffraction pattern acquired at a reference illumination position and a diffraction pattern acquired at an illumination position to be evaluated.

9. The charged particle beam device according to claim 1, wherein
the controller is configured to determine the illumination target region by evaluating at least one of the number of or a position of a diffraction spot for a diffraction pattern acquired at an illumination position to be evaluated.

10. The charged particle beam device according to claim 1, wherein
the controller is configured to determine the illumination target region by using diffraction patterns acquired at a plurality of illumination positions by changing the illumination positions in two different orientations.

11. The charged particle beam device according to claim 1, wherein
the controller is configured to determine the illumination target region by using a plurality of signal components corresponding to different scattering angles.

12. The charged particle beam device according to claim 1, wherein
the controller is configured to determine the illumination target region by using a plurality of signal components corresponding to different scattering orientations.

13. A method for controlling a charged particle beam device used to observe a specimen by illuminating the specimen with a charged particle beam, wherein
the charged particle beam device includes
a movement mechanism configured to hold and move a specimen,
a particle source configured to output the charged particle beam, and
a detector configured to detect a signal generated by illuminating the specimen with the charged particle beam,
the method comprising:
by a controller
determining an illumination target region in the specimen according to the specimen;
moving an illumination position of the charged particle beam in the illumination target region and acquiring a diffraction pattern according to detection signals of the detector at different illumination positions; and
controlling the movement mechanism based on an analysis result of the diffraction pattern to adjust tilt of the specimen.
